(19) United States
(12) Patent Application Publication
(10) Pub. No.: US 2009/0008577 A1
(43) Pub. Date: Jan. 8, 2009

(54) Conformal Doping Using High Neutral Density Plasma Implant

(75) Inventor: Steven R. Walther, Andover, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gloucester, MA (US)

(21) Appl. No.: 11/774,587

(22) Filed: Jul. 7, 2007

(51) Int. Cl. H01J 37/32

(52) U.S. Cl. 250/492.21

(57) ABSTRACT

A plasma doping apparatus includes a plasma source that generates a pulsed plasma. A platen supports a substrate proximate to the plasma source for plasma doping. A structure absorbs a film which provides a plurality of neutrals when desorbed. A bias voltage power supply generates a bias voltage waveform having a negative potential that attracts ions in the plasma to the substrate for plasma doping. A radiation source irradiates the film absorbed on the structure, thereby desorbing the film and generating a plurality of neutrals that scatter ions from the plasma while the ions are being attracted to the substrate, thereby performing conformal plasma doping.

The section headings used herein are for organizational purposes only and should not to be construed as limiting the subject matter described in the present application.

### BACKGROUND OF THE INVENTION

Plasma processing has been widely used in the semiconductor and other industries for many decades. Plasma processing is used for tasks such as cleaning, etching, milling, and deposition. More recently, plasma processing has been used for doping. Plasma doping is sometimes referred to as PLAD or plasma immersion ion implantation (PIII). Plasma doping systems have been developed to meet the doping requirements of some modern electronic and optical devices.

Plasma doping systems are fundamentally different from conventional beam-line ion implantation systems that accelerate ions with an electric field and then filter the ions according to their mass-to-charge ratio to select the desired ions for implantation. In contrast, plasma doping systems immerse the target in a plasma containing dopant ions and bias the target with a series of negative voltage pulses. The term “target” is defined herein as the workpiece being implanted, such as a substrate or wafer being ion implanted. The negative bias on the target repels electrons from the target surface thereby creating a sheath of positive ions. The electric field within the plasma sheath accelerates ions toward the target thereby implanting the ions into the target surface.

The present invention relates to conformal plasma doping. The term “conformal doping” is defined herein as doping of planar and nonplanar surface features in a way that generally preserves the angles of the surface features. In the literature, conformal doping sometimes refers to doping planar and non-planar features with a uniform doping profile over both the planar and nonplanar features. However, conformal doping as defined herein can, but does not necessary, have uniform doping profile over both the planar and nonplanar features of the substrate.

### BRIEF DESCRIPTION OF THE DRAWINGS

The invention, in accordance with preferred and exemplary embodiments, together with further advantages thereof, is more particularly described in the following detailed description, taken in conjunction with the accompanying drawings. The drawings are not necessarily to scale, emphasis instead generally being placed upon illustrating principles of the invention.

FIG. 1 illustrates a schematic diagram of a plasma doping system that performs conformal doping according to the present invention.

FIG. 2A illustrates a pulsed RF waveform that is suitable for plasma doping according to the present invention.

FIG. 2B illustrates a bias voltage waveform generated by a bias voltage supply which applies a negative voltage to the substrate during bias periods to perform plasma doping.

FIG. 2C illustrates an intensity waveform generated by the radiation source that desorbs the absorbed film layer to generate neutrals according to the present invention.

### DETAILED DESCRIPTION

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

It should be understood that the individual steps of the methods of the present invention may be performed in any order and/or simultaneously as long as the invention remains operable. Furthermore, it should be understood that the apparatus and methods of the present invention can include any number or all of the described embodiments as long as the invention remains operable.

The present teachings will now be described in more detail with reference to exemplary embodiments thereof as shown in the accompanying drawings. While the present teachings are described in conjunction with various embodiments and examples, it is not intended that the present teachings be limited to such embodiments. On the contrary, the present teachings encompass various alternatives, modifications and equivalents, as will be appreciated by those of skill in the art. Those of ordinary skill in the art having access to the teachings herein will recognize additional implementations, modifications, and embodiments, as well as other fields of use, which are within the scope of the present disclosure as described herein. For example, although the present invention is described in connection with plasma doping, the methods and apparatus for generating neutrals for scattering ions to enhance conformal doping can also be applied to conventional beam-line ion implantation system.

Three dimensional device structures are now being developed to increase the available surface area of ULSI circuits as well as to extend the device scaling to sub 65 nm technology nodes. For example, three dimensional trench capacitors used in DRAMs, and numerous types of devices using vertical channel transistors, such as the FinFETs (Double or Triple gate) and recessed channel array transistors (RCAT) are being developed in research laboratories. Many of these three dimensional devices require conformal doping of different features on the devices. In addition, many other types of modern electronic and optical devices and nanotechnology microstructures require conformal doping.

Conformal and three-dimensional implants are very difficult to achieve with known ion implantation methods. In particular, conformal or three-dimensional implants are difficult to achieve on devices having high densities, high pitches and/or large vertical aspect ratios that necessitate a very small range of implant angles.

Many known methods of performing conformal ion implants use multiple steps of angled beam-line ion implants to obtain three-dimensional implantation coverage. In these known methods, the target is physically positioned at a plurality of angles relative to the ion beam for predetermined times so that a plurality of angled implants are performed. Performing multiple beam-line angled implants can greatly reduce the throughput of the implantation by a factor equal to the number of ion implants performed. This method of conformal doping has been successfully used for some low density structures made for research and development purposes, but is not practical for manufacturing of most devices.

Plasma doping is well suited for conformal and three-dimensional implants. In plasma doping apparatus, a sheath of positive ions creates an electric field between the sheath boundary and the target surface. This electric field accelerates ions towards the target and implants the ions into the target surface. Conformal plasma doping can be accomplished because the sheath boundary conforms well to the target's surface features when the sheath thickness is less than or equal to the dimension of the undulations in the surface that result from ions impacting the surface at a normal angle of incidence relative to the local surface topology. This phenomenon can be utilized in methods for conformally implanting large targets using plasma immersion doping. However, methods using this phenomenon do not work well for small targets with dense and/or high aspect ratio structures.

Conformal plasma doping can also be performed by creating conditions for ion/neutral scattering in the plasma that result in certain desired distributions of ion angles in the plasma. However, there is only a limited range of ion angles that can presently be created in plasma doping systems by using ion/neutral scattering. Ion/neutral scattering is limited because the probability that undesirable discharges, such as arc discharges and micro-discharges, will occur in the plasma is increased as the density of neutrals in the plasma increases. In addition, the overall plasma uniformity decreases as the density of neutrals increases. Thus, when the ion/neutral scattering reaches a certain level, there will be undesirable discharges and relatively poor uniformity that will be unacceptable for most plasma doping processes.

Conformal doping is achieved with the present invention by using a neutral source that is external to the plasma to scatter ions for ion implantation. In one embodiment, the external neutral source comprises an absorbent film layer that is positioned so that it interacts with ion in the plasma to scatter ions for implantation. For example, the absorbent film layer can be deposited on the target being implanted. Also, the absorbent film layer can be deposited on a structure proximate to the target or somewhere in the processing chamber.

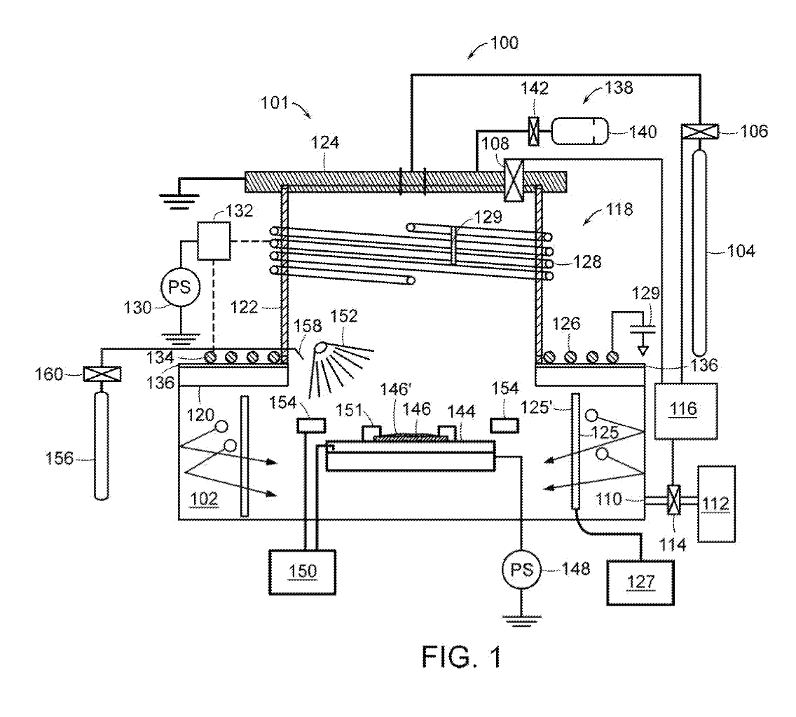

FIG. 1 illustrates a schematic diagram of a plasma doping system 100 that performs conformal doping according to the present invention. It should be understood that this is only one of many possible designs of plasma doping systems that can perform conformal doping according to the present invention. The plasma doping system 100 includes an inductively coupled plasma source 101 having both a planar and a helical RF coil and also a conductive top section. A similar RF inductively coupled plasma source is described in U.S. patent application Ser. No. 10/905,172, filed on Dec. 20, 2004, entitled “RF Plasma Source with Conductive Top Section,” which is assigned to the present assignee. The entire specification of U.S. patent application Ser. No. 10/905,172 is incorporated herein by reference. The plasma source 101 shown in the plasma doping system 100 is well suited for plasma doping applications because it can provide a highly uniform ion flux and the source also efficiently dissipates heat generated by secondary electron emissions.

More specifically, the plasma doping system 100 includes a plasma chamber 102 that contains a process gas supplied by an external gas source 104. The process gas typically contains a dopant species that is diluted in a dilution gas. The external gas source 104, which is coupled to the plasma chamber 102 through a proportional valve 106, supplies the process gas to the chamber 102. In some embodiments, a gas baffle is used to disperse the gas into the plasma source 101. A pressure gauge 108 measures the pressure inside the chamber 102. An exhaust port 110 in the chamber 102 is coupled to a vacuum pump 112 that evacuates the chamber 102. An exhaust valve 114 controls the exhaust conductance through the exhaust port 110.

A gas pressure controller 116 is electrically connected to the proportional valve 106, the pressure gauge 108, and the exhaust valve 114. The gas pressure controller 116 maintains the desired pressure in the plasma chamber 102 by controlling the exhaust conductance and the process gas flow rate in a feedback loop that is responsive to the pressure gauge 108. The exhaust conductance is controlled with the exhaust valve 114. The process gas flow rate is controlled with the proportional valve 106.

The chamber 102 has a chamber top 118 including a first section 120 formed of a dielectric material that extends in a generally horizontal direction. A second section 122 of the chamber top 118 is formed of a dielectric material that extends a height from the first section 120 in a generally vertical direction. The first and second sections 120, 122 are sometimes referred to herein generally as the dielectric window. It should be understood that there are numerous variations of the chamber top 118. For example, the first section 120 can be formed of a dielectric material that extends in a generally curved direction so that the first and second sections 120, 122 are not orthogonal as described in U.S. patent application Ser. No. 10/905,172, which is incorporated herein by reference. In other embodiment, the chamber top 118 includes only a planer surface.

The shape and dimensions of the first and the second sections 120, 122 can be selected to achieve a certain performance. For example, one skilled in the art will understand that the dimensions of the first and the second sections 120, 122 of the chamber top 118 can be chosen to improve the uniformity of plasmas. In one embodiment, a ratio of the height of the second section 122 in the vertical direction to the length across the second section 122 in the horizontal direction is adjusted to achieve a more uniform plasma. For example, in one particular embodiment, the ratio of the height of the second section 122 in the vertical direction to the length across the second section 122 in the horizontal direction is in the range of 1.5 to 5.5.

The dielectric materials in the first and second sections 120, 122 provide a medium for transferring the RF power from the RF antenna to a plasma inside the chamber 102. In one embodiment, the dielectric material used to form the first and second sections 120, 122 is a high purity ceramic material that is chemically resistant to the process gases and that has good thermal properties. For example, in some embodiments, the dielectric material is 99.6% Al₂O₃ or AlN. In other embodiments, the dielectric material is Yittria and YAG.

A lid 124 of the chamber top 118 is formed of a conductive material that extends a length across the second section 122 in the horizontal direction. In many embodiments, the conductivity of the material used to form the lid 124 is high enough to dissipate the heat load and to minimize charging effects that results from secondary electron emission. Typically, the conductive material used to form the lid 124 is chemically resistant to the process gases. In some embodiments, the conductive material is aluminum or silicon.

The lid 124 can be coupled to the second section 122 with a halogen resistant O-ring made of fluoro-carbon polymer, such as an O-ring formed of Chemrz and/or Kalrex materials. The lid 124 is typically mounted to the second section 122 in a manner that minimizes compression on the second section 122, but that provides enough compression to seal the lid 124 to the second section. In some operating modes, the lid 124 is RF and DC grounded as shown in FIG. 1. In addition, in some embodiments, the lid 124 comprises a cooling system that regulates the temperature of the lid 124 and surrounding area in order to dissipate the heat load generated during processing. The cooling system can be a fluid cooling system that includes cooling passages in the lid 124 that circulate a liquid coolant from a coolant source.

In some embodiments, the chamber 102 includes a liner 125 that is positioned to prevent or greatly reduce metal contamination by providing line-of-site shielding of the inside of the plasma chamber 102 from metal sputtered by ions in the plasma striking the inside metal walls of the plasma chamber 102. Such liners are described in U.S. patent application Ser. No. 11,623,739, filed Jan. 16, 2007, entitled “Plasma Source with Liner for Reducing Metal Contamination,” which is assigned to the present assignee. The entire specification of U.S. patent application Ser. No. 11/623,739 is incorporated herein by reference.

In some embodiments, the plasma chamber liner 125 includes a temperature controller 127. The temperature controller 127 is sufficient to maintain the temperature of the liner at a relatively low temperature that is sufficient for absorption of a film layer that generates neutrals during film desorption according to the present invention.

A RF antenna is positioned proximate to at least one of the first section 120 and the second section 122 of the chamber top 118. The plasma source 101 in FIG. 1 illustrates two separate RF antennas that are electrically isolated from one another. However, in other embodiments, the two separate RF antennas are electrically connected. In the embodiment shown in FIG. 1, a planar coil RF antenna 126 (sometimes called a planar antenna or a horizontal antenna) having a plurality of turns is positioned adjacent to the first section 120 of the chamber top 118. In addition, a helical coil RF antenna 128 (sometimes called a helical antenna or a vertical antenna) having a plurality of turns surrounds the second section 122 of the chamber top 118.

In some embodiments, at least one of the planar coil RF antenna 126 and the helical coil RF antenna 128 is terminated with a capacitor 129 that reduces the effective antenna coil voltage. The term “effective antenna coil voltage” is defined herein to mean the voltage drop across the RF antennas 126, 128. In other words, the effective coil voltage is the voltage “seen by the ions” or equivalently the voltage experienced by the ions in the plasma.

Also, in some embodiments, at least one of the planar coil RF antenna 126 and the helical coil RF antenna 128 includes a dielectric layer 134 that has a relatively low dielectric constant compared to the dielectric constant of the Al₂O₃ dielectric window material. The relatively low dielectric constant dielectric layer 134 effectively forms a capacitive voltage divider that also reduces the effective antenna coil voltage. In addition, in some embodiments, at least one of the planar coil RF antenna 126 and the helical coil RF antenna 128 includes a Faraday shield 136 that also reduces the effective antenna coil voltage.

A RF source 130, such as a RF power supply, is electrically connected to at least one of the planar coil RF antenna 126 and helical coil RF antenna 128. In many embodiments, the RF source 130 is coupled to the RF antennas 126, 128 by an impedance matching network 132 that matches the output impedance of the RF source 130 to the impedance of the RF antennas 126, 128 in order to maximize the power transferred from the RF source 130 to the RF antennas 126, 128. Dashed lines from the output of the impedance matching network 132 to the planar coil RF antenna 126 and the helical coil RF antenna 128 are shown to indicate that electrical connections can be made from the output of the impedance matching network 132 to either or both of the planar coil RF antenna 126 and the helical coil RF antenna 128.

In some embodiments, at least one of the planar coil RF antenna 126 and the helical coil RF antenna 128 is formed such that it can be liquid cooled. Cooling at least one of the planar coil RF antenna 126 and the helical coil RF antenna 128 will reduce temperature gradients caused by the RF power propagating in the RF antennas 126, 128. The helical coil RF antenna 128 can include a shunt 129 that can reduce the number of turns in the coil.

In some embodiments, the plasma source 101 includes a plasma igniter 138. Numerous types of plasma igniters can be used with the plasma source 101. In one embodiment, the plasma igniter 138 includes a reservoir 140 of strike gas, which is a highly-ionizable gas, such as argon (Ar), which assists in igniting the plasma. The reservoir 140 is coupled to the plasma chamber 102 with a high conductance gas connection. A burst valve 142 isolates the reservoir 140 from the process chamber 102. In another embodiment, a strike gas source is plumbed directly to the burst valve 142 using a low conductance gas connection. In some embodiments, a portion of the reservoir 140 is separated by a limited conductance orifice or metering valve that provides a steady flow rate of strike gas after the initial high-flow-rate burst.

A platen 144 is positioned in the process chamber 102 a height below the top section 118 of the plasma source 101. The platen 144 holds a target, which is referred to herein as the substrate 146, for plasma doping. In the embodiment shown in FIG. 1, the platen 144 is parallel to the plasma source 101. However, the platen 144 can also be tilted with respect to the plasma source 101. In some embodiments, the platen 144 is mechanically coupled to a movable stage that translates, scans, or oscillates the substrate 146 in at least one direction. In one embodiment, the movable stage is a dither generator or an oscillator that dithers or oscillates the substrate 146. The translation, dithering, and/or oscillation motions can reduce or eliminate shadowing effects and can improve the uniformity and conformality of the ion beam flux impacting the surface of the substrate 146.

In many embodiments, the substrate 146 is electrically connected to the platen 144. A bias voltage power supply 148 is electrically connected to the platen 144. The bias voltage power supply 148 generates a bias voltage that biases the platen 144 and the substrate 146 so that dopant ions in the plasma are extracted from the plasma and impact the substrate 146. The bias voltage power supply 148 can be a DC power supply, a pulsed power supply, or a RF power supply.

In one embodiment of the present invention, the plasma doping system 100 includes a temperature controller 150 that is used to control the temperature of the platen 146 and the temperature of the substrate 146. The substrate 146 is positioned in good thermal contact with the platen 146. Also, in one embodiment, cooled Eclamps 151 are used to secure the substrate 146 to the platen 146 and also to control the temperature of the substrate 146. The temperature controller 150 and/or the cooled Eclamps 151 are designed to maintain the temperature of the substrate 146 at a relatively low temperature that is sufficient for absorption of a film layer 146′ that generates neutrals during film desorption according to the present invention.

In some embodiments, a structure 154 other than the target or substrate 146 is used as the neutral source. Numerous types of structures can be used. For example, the structure 154 can be a structure that is cooled by the temperature controller 150 (or another temperature controller) and that has surface features designed to absorb a relatively high volume of atoms or molecules per unit area. For example, the structure 154 can have a plurality of high aspect-ratio features that absorb films on both vertical and horizontal surfaces. In one embodiment, the structure surrounds 154 the target or substrate 146.

Also, in one embodiment, a controlled amount of gas, which is used for absorbing the film layer 146′, is directed to the substrate 146 at predetermined times relative to bias voltage pulses generated by the bias voltage power supply 148 in order to enhance re-absorption of the film layer 146′ on the substrate 146. In various embodiments, the gas can be the same gas as the gas in the gas source 104 used for plasma doping, which includes the dopant species and a dilution gas, or it can be a different gas. In one specific embodiment, a separate absorption gas is supplied by a second external gas source 156 and a nozzle 158 directed towards the substrate 146 and/or the structure 154. A valve 160 controls the flow rate and timing of the release of the absorption gas through the nozzle 158.

In various embodiments, the nozzle 158 can be a single nozzle or an array of nozzles. In addition, a plurality of nozzles with separate gas sources can be used. More than one type of gas can be dispensed from the plurality of nozzles. The nozzle 158 can also be located in various positions relative to the substrate 146 or the structure 154. For example, in one embodiment, the nozzle 158 is located directly over the substrate 146 or structure 154. Also, in some embodiments, a gas baffle is positioned proximate to the substrate 146 or structure 154 so as to locally increase the partial pressure of the absorption gas proximate to the substrate 146 or structure 154. Also, in some embodiments, the nozzle 158 is located in an anode that provides an electrical ground for the plasma.

In some embodiments, a control output of the bias voltage power supply 148 is electrically connected to a control input of the valve 160 so that the pulses generated by the bias voltage power supply 148 and the operation of the valve 160 are synchronized in time. In other embodiments, a controller is used to control the operation of both the bias voltage power supply 148 and the valve 160 so that the absorption gas is injected proximate to the substrate 146 or the structure 154 during re-absorption times. Re-absorption is typically performed while plasma doping is terminated. However, re-absorption can also be performed during plasma doping.

In one embodiment of the present invention, the plasma doping system includes a radiation source 152 that provides a burst or pulse of radiation that rapidly desorbs the absorbed film 146′. Numerous types of radiation sources can be used. For example, in various embodiments, the radiation source 152 can be an optical source such as a flash lamp, a laser, or a light emitting diode. Also, the radiation source 152 can be an electron beam source or an X-ray source. In some embodiments, the plasma itself generates the radiation.

One skilled in the art will appreciate that the there are many different possible variations of the plasma source 101 that can be used with the features of the present invention. See for example, the descriptions of the plasma sources in U.S. patent application Ser. No. 10/908,009, filed Apr. 25, 2005, entitled “Tilted Plasma Doping.” Also see the descriptions of the plasma sources in U.S. patent application Ser. No. 11/163,303, filed Oct. 13, 2005, entitled “Conformal Doping Apparatus and Method.” Also see the descriptions of the plasma sources in U.S. patent application Ser. No. 11/163,307, filed Oct. 13, 2005, entitled “Conformal Doping Apparatus and Method.” In addition, see the descriptions of the plasma sources in U.S. patent application Ser. No. 11/566,418, filed Dec. 4, 2006, entitled “Plasma Doping with Electronically Controllable implant Angle.” The entire specification of U.S. patent application Ser. Nos. 10/908,009, 11/163,303, 11/163,307 and 11/566,418 are herein incorporated by reference.

In operation, the RF source 130 generates an RF current that propagates in at least one of the RF antennas 126 and 128. That is, at least one of the planar coil RF antenna 126 and the helical coil RF antenna 128 is an active antenna. The term “active antenna” is herein defined as an antenna that is driven directly by a power supply. In some embodiments of the plasma doping apparatus of the present invention, the RF source 130 operates in a pulsed mode. However, the RF source can also operate in the continuous mode.

In some embodiments, one of the planar coil antenna 126 and the helical coil antenna 128 is a parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna positioned in electromagnetic communication with the parasitic antenna. In the embodiment shown in FIG. 1, the active antenna is one of the planar coil antenna 126 and the helical coil antenna 128 powered by the RF source 130. In some embodiments of the invention, one end of the parasitic antenna is electrically connected to ground potential in order to provide antenna tuning capabilities. In this embodiment, the parasitic antenna includes the coil adjuster 129 that is used to change the effective number of turns in the parasitic antenna coil. Numerous different types of coil adjusters, such as a metal short, can be used.

The RF currents in the RF antennas 126, 128 then induce RF currents into the chamber 102. The RF currents in the chamber 102 excite and ionize the process gas so as to generate a plasma in the chamber 102. The plasma chamber liner 125 shields metal sputtered by ions in the plasma from reaching the substrate 146.

The bias voltage power supply 148 biases the substrate 146 with a negative voltage that attracts ions in the plasma towards the substrate 146. During the negative voltage pulses, the electric field within the plasma sheath accelerates ions toward the substrate 146 which implants the ions into the surface of the substrate 146.

A process of absorbing a film layer and then rapidly desorbing the film layer to generate neutrals that scatter ions for ion implantation is used to enhance the conformality of the plasma doping. Many different types of external neutral sources can be used. In one embodiment, the substrate 146 itself is the neutral source. In this embodiment, the substrate 146 is cooled by the temperature controller 150 to a temperature that absorbs a layer 146′ of atoms or molecules. For example, the substrate 146 can be cooled by the temperature controller 150 to absorb at least one of a layer of the dopant species or a layer of a dilution gas that is present in the process gas supplied by the external gas source 104. For example, dopant species, such as AsH₃ or B₂H₆, are used.

Alternatively, the substrate 146 can be pre-cooled prior to loading the substrate 146 into the plasma doping system 100 so that the substrate 146 absorbs gas molecules. However, if the substrate 146 is pre-cooled prior to loading, care must be taken so ensure that only atoms and molecules are absorbed that will not interfere with the doping process. In one embodiment, the substrate 146 is pre-cooled in the presence of the dopant species or the dilution gas used for ion implantation so that only a layer of the dopant species and/or the dilution gas is absorbed on the surface of the substrate 146.

In other embodiments, a structure 154 other than the target or substrate 146 is used as the neutral source. Numerous types of structures can be used. For example, the structure 154 can be a structure that has surface features designed to absorb a relatively high volume of atoms or molecules per unit area. In some embodiments, the structure 154 is cooled by the temperature controller 150. Alternatively, a separate temperature controller can be used. In other embodiments, the structure 154 is pre-cooled prior to inserting the structure 154 in the plasma doping system 100. In these embodiments, the structure 154 is pre-cooled in an environment where only atoms and molecules are absorbed that will not interfere with the doping process. For example, the structure 154 can be pre-cooled in the presence of the dopant species or the dilution gas used for ion implantation so that only a layer of the dopant species and/or the dilution gas is absorbed on the surface of the substrate 146.

In some embodiments, an absorption gas is injected into the chamber 102 from the nozzle 158 and is directed to the substrate 146 to enhance re-absorption of the film layer 146′ on the substrate 146. The absorption gas can be the same gas as the dopant gas in the gas source 104 used for plasma doping or can be another gas that generates neutrals when exposed to radiation generated by the radiation source 152 and that does not interfere with the plasma doping process.

In some embodiments, the bias voltage power supply 148 sends an electrical signal to the valve 160 which synchronizes the operation of the valve 160 in time with the generation of the bias voltage pulses. In other embodiments, a controller sends electrical signals to both the valve 160 and the bias voltage power supply 148 which synchronizes the operation of the valve 160 in time with the generation of the bias voltage pulses. For example, the controller or bias voltage power supply 148 can send a signal to the valve 160 that opens the valve 160 so that absorption gas is injected proximate to the substrate 146 or the structure 154 during re-absorption times when plasma doping is terminated.

The absorbed film layer 146′ is then desorbed by exposure to the radiation source 152. In many embodiments, the absorbed film layer 146′ is rapidly desorbed. In one embodiment, the absorbed film layer 146′ is desorbed by exposure to an optical radiation source, such as a flash lamp, a laser, and/or a light emitting diode. For example, a flash lamp that emits visible and/or ultraviolet light can be used to rapidly desorb the absorbed film layer 146′. In some embodiments, the plasma generated by the plasma source 101 is the radiation source. In these embodiments, the absorbed film layer 146′ is desorbed by exposure to the plasma generated by the plasma source 101. For example, the plasma source 101 can generate a pulsed plasma having parameters that are chosen to rapidly desorb the absorbed film layer 146′.

The resulting desorbed gas atoms and/or molecules then provide a locally high neutral density that scatter ions generated by the plasma which are attracted to the substrate 146 to achieve a more conformal implant. Introducing a locally high neutral density will not significantly increase the global pressure in the plasma source 101 and, therefore, will not introduce any significant undesirable electrical discharges and/or will not cause a significant reduction in plasma doping uniformity.

In other embodiments, other types of radiation sources are used to desorb the absorbed film layer 146′. For example, in one embodiment of the present invention, an electron beam source is used to generate an electron beam which is directed to the absorbed film layer 146′. The electron beam rapidly desorbs the absorbed film layer 146′. The desorbed gas atoms and/or molecules then provide a locally high neutral density that scatters ions from the plasma that are attracted to the substrate 146 achieve a more conformal ion implant.

In yet another embodiment of the present invention, an X-ray source is used to generate an X-ray beam which is directed to the absorbed film layer 146′. The X-ray beam rapidly desorbs the absorbed film layer 146′. The desorbed gas atoms and/or molecules then provide a locally high neutral density that scatters ions from the plasma that are attracted to the substrate 146 achieve a more conformal implant.

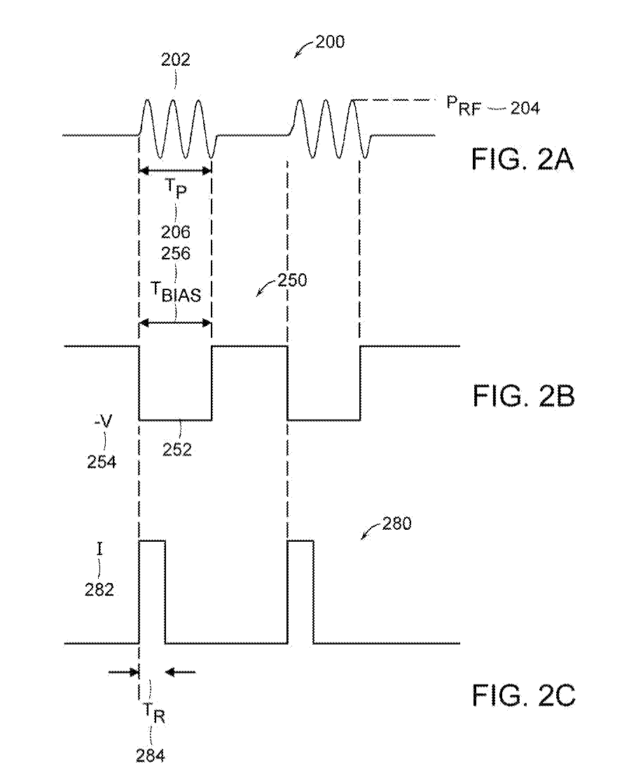

FIGS. 2A-2C present timing diagrams illustrating the generation of the plasma and the generation of neutrals from an external source (i.e. a source other than the plasma) for performing conformal plasma doping according to the present invention. In one embodiment of the present invention, the plasma source 101 is operated in a pulsed mode of operation during conformal plasma doping. FIG. 2A illustrates a pulsed RF waveform 200 that is suitable for plasma doping according to the present invention. The pulsed RF waveform 200 is at ground potential until an RF pulse 202 is initiated. The RF pulse 202 has a power level that is equal to P_{RF} 204, which is chosen to be suitable for plasma doping. The RF pulse 202 terminates after the pulse period T_{P} 206 and then returns to ground potential. The pulsed RF waveform 200 then periodically repeats with a duty cycle that is determined by the desired plasma process parameters and by the re-absorption rate of the absorbed film layer 146′ used to create neutrals.

FIG. 2B illustrates a bias voltage waveform 250 that is generated by the bias voltage supply 148 which applies negative voltage pulses 252 with voltage 254 to the substrate 146 during a bias period T_{Bias} 256 to perform plasma doping. The negative voltage 254 attracts ions in the plasma to the substrate 146. The bias period T_{Bias} 256 can be synchronized to the pulse period T_{P} 206 of the pulsed RF waveform 200 so that the plasma is energized only during the bias period T_{Bias} 256. The bias voltage waveform 250 then periodically repeats with a duty cycle that is determined by the desired plasma process parameters and also by the re-absorption rate of the absorbed film layer 146′ used to create neutrals.

In various embodiments, both the pulse frequency and the duty cycle of the bias voltage waveform 250 are chosen so that there is sufficient time for re-absorption of the film 146′ to occur on the substrate 146 or structure 154. For example, in one embodiment, the pulse frequency and duty cycle of the bias voltage waveform 250 is chosen so that sufficient re-absorption occurs between individual pulses. In other embodiments, the bias voltage waveform 250 comprises a pulse train having a predetermined number of pulses and a delay between pulse trains having a predetermined time, where the delay is sufficient for re-absorption of the film 146′ to occur on the substrate 146 or structure 154. For example, in one embodiment, a bias voltage waveform 250 having a pulse train including 100-1,000 pulses with a delay between pulse trains in the millisecond range is used generate sufficient neutrals for conformal plasma doping.

FIG. 2C illustrates a waveform 280 of the intensity I 282 of the radiation source 152 that desorbs the absorbed film layer 146′ to generate neutrals according to the present invention. In the embodiments shown in FIG. 2C, the intensity I 282 of the radiation source 152 is rapidly pulsed on at the onset of the RF pulse 202. It should be understood that in various other embodiments, the intensity I 282 of the radiation source 152 can be more gradually initiated. Also, in the embodiment shown in FIG. 2C, the radiation period T_{R} 284 is a fraction of the pulse period T_{P} 206 and the bias period T_{Bias} 256. It should also be understood that in various embodiments, the radiation period T_{R} 284 can be the same length as the pulse period T_{P} 206 and/or the bias period T_{Bias} 256 or even longer than the T_{P} 206 and/or the bias period T_{Bias} 256. The desired length of the radiation period T_{R} 284 is related to the re-absorption rate of the film 146′ and to the intensity I 282.

The radiation source 152 can be synchronized with bias voltage power supply 148 that biases the substrate 146 with the negative voltage pulses 252 that attract ions in the plasma towards the substrate 146. For example, the radiation source 152 can be synchronized with bias voltage power supply 148 so that the radiation source provides a burst of radiation either directly before the negative voltage pulses 252 or simultaneously with the negative voltage pulses 252 that attract ions to the substrate 146 for conformal plasma doping. The duty cycle of the pulsed RF waveform 200 is chosen so that the absorbed film layer 146′ is sufficiently reabsorbed between negative voltage pulses 252.

One skilled in the art will appreciate that the present invention for conformal doping can also be used with conventional beam line ion implantation systems. Beam line ion implantation systems that are well known in the art. The target or substrate in these systems can be used to absorb a film as described herein. Alternatively, a structure, such as the structure 154 described in connection with FIG. 1, can be used to absorb a film according to the present invention. A radiation source can then be used to desorb the absorbed film to generate neutrals as described herein. The neutrals scatter ions from the ion beam, thereby implanting a more conformal ion implantation profile.

### Equivalents

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention.

What is claimed is:

1. A plasma doping apparatus comprising:
a. a plasma source that generates a pulsed plasma;
b. a platen that supports a substrate proximate to the plasma source for plasma doping;
c. a structure that absorbs a film which generates a plurality of neutrals when desorbed; and
d. a bias voltage power supply having an output that is electrically connected to the platen, the bias voltage power supply generating a bias voltage waveform having a negative potential that attracts ions in the plasma to the substrate for plasma doping; and
e. a radiation source that irradiates the film absorbed on the structure to desorb the absorbed film and to generate the plurality of neutrals, the plurality of neutrals scattering ions from the plasma while the ions are attracted to the substrate, thereby performing conformal plasma doping.

2. The plasma doping apparatus of claim 1 wherein the structure comprises the substrate.

3. The plasma doping apparatus of claim 1 further comprising a temperature controller that changes a temperature of the structure to a temperature that enhances absorption of the film.

4. The plasma doping apparatus of claim 1 further comprising a nozzle that injects an absorption gas proximate to the structure, the absorption gas enhancing absorption of the film.

5. The plasma doping apparatus of claim 1 wherein the radiation source comprises an optical radiation source.

6. The plasma doping apparatus of claim 5 wherein the optical radiation source comprises at least one of a flash lamp, a laser, and a light emitting diode.

7. The plasma doping apparatus of claim 1 wherein the radiation source comprises the pulsed plasma.

8. The plasma doping apparatus of claim 1 wherein the radiation source comprises an electron beam radiation source.

9. The plasma doping apparatus of claim 1 wherein the radiation source comprises an X-ray radiation source.

10. The plasma doping apparatus of claim 1 wherein the radiation source generates a burst of radiation that rapidly desorbs the absorbed film.

11. The plasma doping apparatus of claim 1 wherein the neutrals generated by desorbing the absorbed film provide a locally high neutral density proximate to the substrate that does not significantly reduce doping uniformity.

12. A method of conformal plasma doping, the method comprising:
a. positioning a substrate on a platen;
b. absorbing a film on a structure positioned proximate to the platen;
c. generating a plasma proximate to the platen;
d. desorbing the absorbed film on the structure, thereby generating a plurality of neutrals; and
e. biasing the platen with a bias voltage waveform having a negative potential that attracts ions in the plasma to the substrate for plasma doping, the plurality of neutrals scattering ions from the plasma while the ions are being attracted to the substrate, thereby performing conformal plasma doping.

13. The method of claim 12 wherein the desorbing the absorbed film on the structure comprises irradiating the absorbed film on the structure.

14. The method of claim 13 wherein the irradiating the absorbed film on the structure comprises generating a burst of radiation that rapidly desorbs the absorbed film.

15. The method of claim 13 wherein the irradiating the absorbed film on the structure comprises irradiating the absorbed film with optical radiation.

16. The method of claim 13 wherein the irradiating the absorbed film on the structure comprises irradiating the absorbed film with electron beam radiation.

17. The method of claim 13 wherein the irradiating the absorbed film on the structure comprises irradiating the absorbed film with X-ray radiation.

18. The method of claim 12 wherein the desorbing the absorbed film and the biasing the platen with the bias voltage waveform having the negative potential occurs substantially simultaneously in time.

19. The method of claim 12 wherein the desorbing the absorbed film and the biasing the platen with the bias voltage waveform having the negative potential are synchronized in time.

20. The method of claim 12 wherein the absorbing the film on the structure comprises controlling a temperature of the structure to a temperature that enhances absorption of the film.

21. The method of claim 12 wherein the absorbing the film on the structure comprises absorbing the film on the structure prior to positioning the substrate on the platen.

22. The method of claim 12 wherein the absorbing the film on the structure comprises injecting an absorption gas proximate to the substrate.

23. The method of claim 12 wherein the generating the plurality of neutrals comprises providing a locally high neutral density proximate to the substrate that does not significantly reduce doping uniformity.

24. A conformal doping apparatus, the apparatus comprising:
a. a means for absorbing a film on a structure positioned proximate to a platen supporting a substrate;
b. a means for generating ions containing a dopant species;
c. a means for desorbing the absorbed film on the structure to generate a plurality of neutrals that scatter ions containing the dopant species, thereby performing conformal doping.

25. The conformal doping apparatus of claim 24 wherein the structure comprises the substrate.

26. The conformal doping apparatus of claim 24 wherein the means for generating ions containing the dopant species comprises generating an ion beam containing the dopant species.

27. The conformal doping apparatus of claim 24 wherein the means for generating ions containing the dopant species comprises generating a plasma containing the dopant species.
